(19) United States
(12) Patent Application Publication
(10) Pub. No.: US 2019/0294851 A1
(43) Pub. Date: Sep. 26, 2019

(54) DISPLAY PANEL FOR PROVIDING SENSING LIGHT TO OPTICAL FINGERPRINT SENSOR AND FINGERPRINT SENSING SYSTEM INCLUDING THEREOF

(71) Applicant: Samsung Electronics Co., Ltd., Suwon-si (KR)

(72) Inventors: Dae-young CHUNG, Seoul (KR); Sang-hyun Cho, Hwaseong-si (KR); Hee-chang Hwang, Seoul (KR); Sung-mok Lee, Gunpo-si (KR); Jong-sung Lee, Suwon-si (KR)

(73) Assignee: Samsung Electronics Co., Ltd., Suwon-si (KR)

(21) Appl. No.: 16/356,351

(22) Filed: Mar. 18, 2019

(30) Foreign Application Priority Data
Mar. 26, 2018 (KR) 10-2018-0034758
Nov. 23, 2018 (KR) 10-2018-0146609

(51) Int. Cl. G06K 9/00; H01L 27/32; G06F 3/044

(52) U.S. Cl. CPC G06K 9/0004; H01L 27/323; G06F 3/044; H01L 27/3234

(57) ABSTRACT

A display panel for providing sensing light to an optical fingerprint sensor and a fingerprint sensing system including the display panel are provided. A display panel according to an example embodiment includes a window glass, a phase change layerunder the window glass and delaying a phase of light, a polarizing plate under the phase change layer, a pixel layer under the polarizing plate and having a plurality of pixels each emitting light, and a substrate under the pixel layer and configured to transmit the sensing light generated by scattering light emitted from at least a part of the plurality of pixels by a fingerprint on the window glass.

### CROSS-REFERENCE TO RELATED APPLICATIONS

This application claims the benefit of Korean Patent Application Nos. 10-2018-0034758 and 10-2018-0146609, respectively filed on Mar. 26, 2018 and Nov. 23, 2018, in the Korean Intellectual Property Office, the disclosures of which are incorporated herein in their entirety by reference.

### BACKGROUND

The inventive concepts relate to a display panel, and more particularly, to a structure of a display panel that provides sensing light to an optical fingerprint sensor under the display panel.

Recently, as technology related to wired/wireless communication technology and a smart device has rapidly developed, to perform user authentication, which is one of the security methods that securely use the technology, a method of using a user fingerprint is increasing. There is a demand for an on-display fingerprint sensor in which a fingerprint sensor is mounted on a touch screen (or display) to improve or optimize the usability and size of a mobile device, such as a smart phone, and a tablet PC. An example of a fingerprint sensor for an on-display (or built-in fingerprint sensor) includes an optical fingerprint sensor provided under the display panel. An organic light-emitting diode (OLED) in a display panel operates as a light source, light emitted from an OLED light source is transmitted to and reflected from a fingerprint, and light generated by the optical fingerprint sensor may be read by an optical sensor such as a photodiode to generate a fingerprint image.

### SUMMARY

The inventive concepts provide a display panel structure that provides an optical signal that enables an optical fingerprint sensor to generate an undistorted and undamaged fingerprint image, and a fingerprint sensing system that generates undistorted and undamaged fingerprint images.

According to an aspect of the inventive concepts, there is provided a display panel configured to provide sensing light to an optical fingerprint sensor, the display panel including a window glass, a phase change layer under the window glass for delaying a phase of light, a polarizing plate under the phase change layer, a pixel layer under the polarizing plate and having a plurality of pixels each of which emits light, and a substrate under the pixel layer and configured to transmit the sensing light generated by scattering light emitted from at least a part of the plurality of pixels by a fingerprint on the window glass.

According to another aspect of the inventive concepts, there is provided a display panel including a pixel layer on the substrate and including a plurality of pixels, a polarizing layer on the pixel layer, a window glass on the polarizing layer, and a filter between the polarizing layer and the window glass and configured to block interface reflection light that is emitted from at least a part of the plurality of pixels and reflected from one surface of the window glass.

According to another aspect of the inventive concepts, there is provided a fingerprint sensing system including a display panel, and a fingerprint sensor configured to generate a fingerprint image based on sensing light generated by scattering and reflecting light emitted from the display panel on a fingerprint. The display panel includes a pixel layer including a plurality of pixels emitting light, a polarizing plate on the pixel layer, a retarder on the polarizing plate and configured to retard the phase of light by 45 degrees, and a window glass on the retarder.

### BRIEF DESCRIPTION OF THE DRAWINGS

Embodiments of the inventive concepts will be more clearly understood from the following detailed description taken in conjunction with the accompanying drawings in which:

FIG. 1 is a structural diagram illustrating an example of a fingerprint sensing system including a display panel according to some embodiments of the inventive concepts;

FIG. 2 is an example of a vertical sectional view of a display panel according to some embodiments of the inventive concepts;

FIG. 3A illustrates a path through which interface reflection light is removed in the display panel according to some embodiments of the inventive concepts, FIG. 3B illustrates a path along which the scattered reflection light enters a fingerprint sensor in the display panel according to some embodiments of the inventive concepts;

FIG. 4 illustrates an example of a fingerprint sensor according to some embodiments of the inventive concepts;

FIGS. 5A and 5B are views explaining a change of an optical fingerprint image based on a state of a finger in a fingerprint sensing system to which a display panel based on a comparative example of a display panel, according to some embodiments of the inventive concepts, is applied;

FIG. 6 is a diagram for comparing and explaining a fingerprint image generated in a fingerprint sensing system using a display panel according to some embodiments of the inventive concepts and a fingerprint image generated in the fingerprint sensing system using the display panel based on a comparative example;

FIGS. 7A to 7C are example vertical sectional views showing a structure of a display panel according to embodiments of the inventive concepts;

FIG. 8 is a diagram showing an electronic device including a display panel according to some embodiments of the inventive concepts; and

FIG. 9 is a diagram illustrating a smartphone according to some embodiments of the inventive concepts.

### DETAILED DESCRIPTION OF EMBODIMENTS

Hereinafter, embodiments of the inventive concepts will be described in detail with reference to the accompanying drawings.

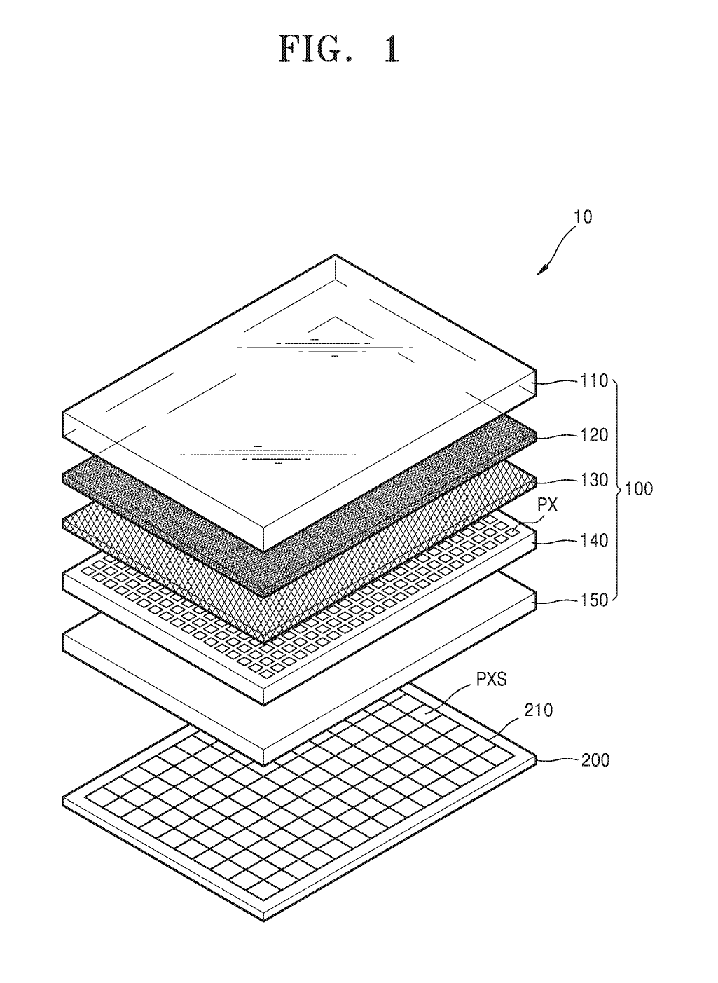

FIG. 1 is a structural diagram showing an example of a fingerprint sensing system including a display panel according to some embodiments of the inventive concepts.

A fingerprint sensing system 10 may be mounted on an electronic device such as a smart phone, a laptop computer, a tablet personal computer (PC), a personal digital assistant (PDA), an enterprise digital assistant (EDA), a digital still camera, a digital video camera, a portable multimedia player (PMP), a portable navigation device (PND), a smart security device, a door lock, a smart home appliance, a wearable device, an internet of things (IoT) device, a device, an internet of everything (IoE) device, a drone, or an e-book. However, the inventive concepts are not limited thereto, and the fingerprint sensing system 10 may be mounted on various types of electronic devices having a display function and a fingerprint recognition function.

Referring to FIG. 1, a fingerprint sensing system 10 may include a display panel 100 and/or a fingerprint sensor 200. The display panel 100 may be on an upper portion of the fingerprint sensor 200. The fingerprint sensor 200 may be an optical-type fingerprint sensor that generates a fingerprint image by sensing received light through the image sensor. Since light emitted from the display panel 100 senses light reflected by a ridge and a valley between ridges of a fingerprint, the fingerprint sensor 200 may reconstruct the sensed signal to generate the fingerprint image. Such an optical fingerprint sensor may be referred to as a camera fingerprint sensor.

The display panel 100 may include various types of display panels. In some embodiments, the display panel 100 may be an organic light-emitting diode (OLED) display panel including an OLED layer including an OLED emitting light of one or a plurality of colors. However, embodiments of the inventive concepts are not limited thereto, and the fingerprint sensing system 10 according to some embodiments of the inventive concepts may correspond to various types of display panels such as a liquid crystal display (LCD) panel that performs a display operation using a light emitting diode (LED) display panel, an active-matrix OLED (AMOLED) display panel, a general backlight, or an OLED. Alternatively, in addition to the above-described display panels, when the light from the light source of the display panel is reflected by the fingerprint and is transmitted in the back plane direction of the display panel (or in the direction of the fingerprint sensor 200), the corresponding display panel may be applied to the display panel 100 according to some embodiments of the inventive concepts.

The display panel 100 according to some embodiments of the inventive concepts may include a window glass 110, a phase delay layer 120, a polarizing layer 130, a pixel layer 140, and/or a substrate 150. In addition, the display panel 100 may further include other layers between the components thereof. For example, the display panel 100 may further include a touch electrode layer, a force electrode layer, and the like.

The display panel 100 may have a structure in which the pixel layer 140, the polarizing layer 130, the phase delay layer 120, and/or a window glass 110 are stacked on the substrate 150. The polarizing layer 130 (or referred to as a polarizing plate) may polarize incident light by transmitting the incident light, for example, a component that vibrates in a designated phase axis (e.g., a direction of 90 degrees) among components of the light emitted from the pixel layer 140 or the incident light emitted from the phase delay layer 120 (or referred to as a phase retarder or a phase change layer). A linear polarizing plate or linearly polarized light and a phase retarder may constitute the polarizing layer 130.

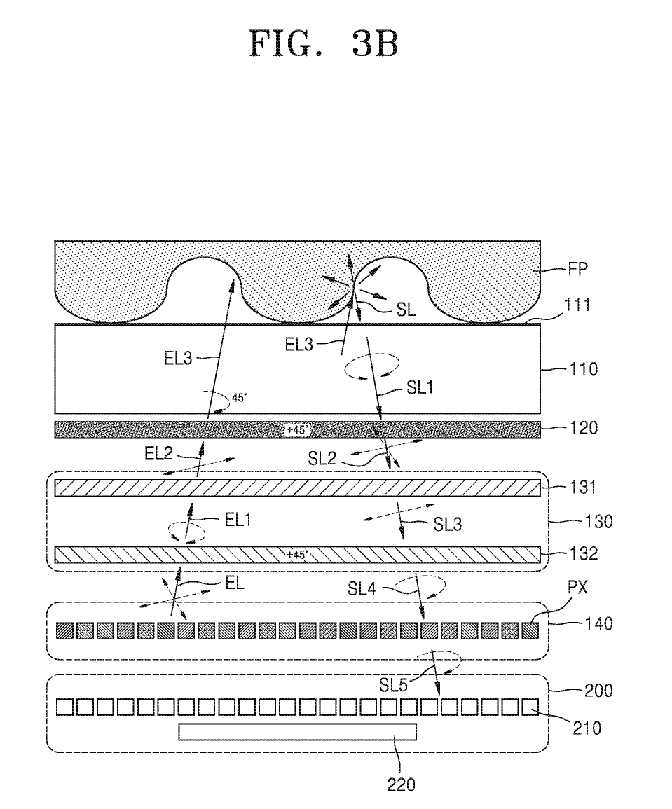

The phase delay layer 120 may delay a phase of incident light, for example, the light emitted from the polarizing layer 130 or the light emitted from the window glass 110, by λ*(N/4) (where λ is wavelength, and N is one of 1, 3, 5, or 7). For example, the phase delay layer 120 may delay the phase of incident light by 45 degrees (e.g., λ/4). Since the phase delay layer 120 is between the polarizing layer 130 and the window glass 110, the interface reflection light generated by interfacial reflection of the light emitted from the pixel layer 140 on an upper surface of the window glass 110 may be blocked from entering the substrate 150, and only the scattered reflection light generated when the light emitted from the pixel layer 140 hits valleys or ridges of the fingerprint may be incident on the substrate 150. This will be described later in more detail with reference to FIGS. 3A and 3B.

The fingerprint sensor 200 may be implemented as a semiconductor chip or a semiconductor package and may be attached to one surface of the display panel 100. The fingerprint sensor 200 may be implemented with an image sensor such as a CMOS image sensor (CIS) or a charge coupled device (CCD) and may include a pixel array 210 including a plurality of sensing pixels PXS (e.g., light-receiving pixels). The pixel array 210 may be implemented as a semiconductor layer or a semiconductor chip in which a plurality of photoelectric conversion elements (e.g., photodiodes, phototransistors, photogates, and pinned photodiodes) are formed. In the following description, it is assumed that a photoelectric conversion element in the sensing pixel PXS is implemented as a photodiode.

The fingerprint sensor 200 may sense fingerprints that are placed on or near the display panel 100. In a device equipped with the fingerprint sensing system 10 according to some embodiments of the inventive concepts, when a fingerprint contacts on the display panel 100 without needing to mount a separate button for fingerprint recognition, the fingerprint may be recognized. For example, when a user's fingerprint is on the window glass 110 of the display panel 100, the light from the OLED in the display panel 100 may be transmitted as a light source and scattered and reflected by the user's fingerprint, and the scattered reflection light may be transmitted to the pixel array 210 of the fingerprint sensor 200 through the substrate 150 of the display panel 100.

The sensing pixel PXS may sense light scattered and reflected by different regions of the fingerprint and may generate an electric signal corresponding to the sensed light. Each sensing pixel PXS may generate an electrical signal corresponding to the scattered reflection light on a ridge of the fingerprint or may generate an electrical signal corresponding to the scattered reflection light on a valley between ridges. The amount of light sensed by the photodiode may vary depending on the type of the fingerprint reflecting by the light, and electric signals having different levels may be generated depending on the amount of sensed light. That is, the electric signals from the plurality of sensing pixels PXS may include contrast (or lightness) information (or image information), respectively, and it may be determined whether a region corresponding to each sensing pixel PXS is a ridge or a valley through the processing operation on the electrical signal, and a whole fingerprint image may be constructed by combining the determined information.

In FIG. 1, the pixel array 210 of the fingerprint sensor 200 corresponds to the entire area of the display panel 100, but embodiments of the inventive concepts are limited thereto. As an example, the pixel array 210 may correspond to a part of the area of the display panel 100, and thus the fingerprint may be sensed when a user's fingerprint is located in a specific area of the display panel 100.

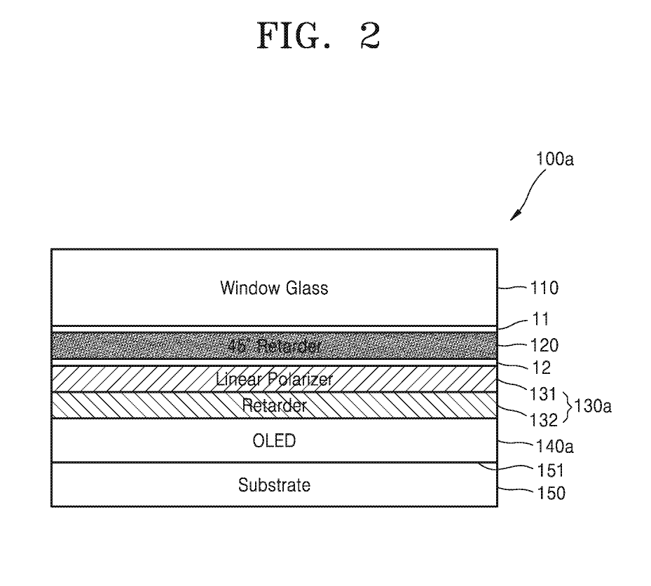

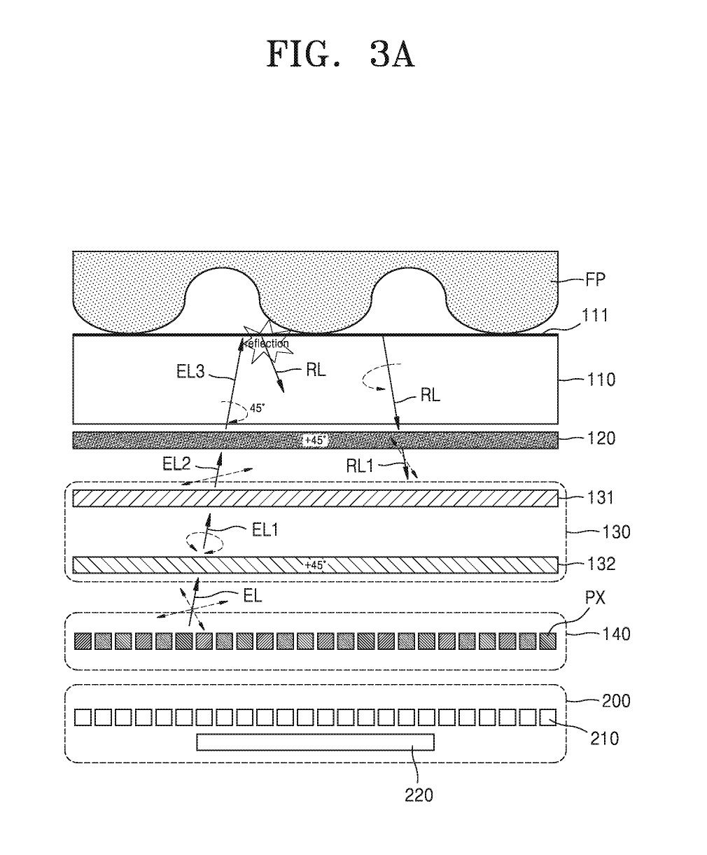

FIG. 2 is an example of a vertical cross-sectional view of a display panel according to some embodiments of the inventive concepts; An OLED display panel will be described as an example.

Referring to FIG. 2, a display panel 100a has a structure in which a substrate 150, an OLED pixel layer 140a, a polarizing layer 130a, a phase delay layer 120, and/or a window glass 110 are stacked. However, the inventive concepts are not limited thereto, and other layers may be between respective constituent elements in a range in which the stacking order of the constituent elements is maintained.

In the display panel 100a according to an example embodiment of the inventive concepts, the phase delay layer 120 may be stacked on an upper part of the polarizing layer 130a and a lower part of the window glass 110. The phase delay layer 120 may be attached in the display panel 100a by a first adhesive layer 11 and a second adhesive layer 12. For example, the first adhesive layer 11 and the second adhesive layer 12 may be formed of a transparent optical adhesive material such as optical clear resin (OCR), and optically clear adhesive (OCA).

The substrate 150 may be formed of a transparent insulating material such as glass, quartz, ceramic, and plastic. In some embodiments, the substrate 150 may be formed of a material having solubility. A thin film transistor (TFT) backplane may be formed on one surface 151 of the substrate 150 to apply a signal to the pixels. The OLED pixel layer 140a may be formed on the substrate 150. The OLED pixel layer 140a may include an organic layer and electrodes constituting the OLED.

The polarizing layer 130a may be formed on the OLED pixel layer 140a. The polarizing layer 130a may include a linear polarizing plate 131 and a retarder 132. The retarder 132 may delay a phase of incident light by 45 degrees. The linear polarizing plate 131 transmits only the component that vibrates only in one direction, for example, 90 degrees, of components of the incident light, and thus the incident light may be linearly polarized. In this manner, the polarizing layer 130a including the linear polarizing plate 131 and the retarder 132 configured to retard the phase by 45 degrees may be referred to as a circular polarizing plate.

The phase delay layer 120 may be formed on the polarizing layer 130a, and the phase delay layer 120 may include a retarder that delays the phase of incident light by 45 degrees. The window glass 110 for protecting the display panel 100a from the outside may be on the polarizing layer 130a.

In the optical configuration of the display panel 100a of FIG. 2, the linear polarizing plate 131 of the polarizing layer 130a may be between the retarder 132 and the phase delay layer 120, the phase delay layer 120 may be between the linear polarizing plate 131 and the window glass 110. In this structure, the phase delay layer 120 may function as a filter in which the light emitted from the OLED pixel layer 140a removes interface reflection light reflected from an interface surface between one surface of the window glass 110 and an outer air layer.

FIG. 3A shows a path along which the interface reflection light is removed in the display panel according to an example embodiment of the inventive concepts, and FIG. 3B shows a path along which the scattered reflection light enters the fingerprint sensor in the display panel according to an example embodiment of the inventive concepts.

Referring to FIG. 3A, emission light EL emitted from at least some of the plurality of pixels of the pixel layer 140 may be delayed in phase while passing through the retarder 132 of the polarizing layer 130. For example, the retarder 132 may delay the phase of the emission light EL by 45 degrees.

Light EL1 output from the retarder 132 may be incident on the linear polarizing plate 131. The linear polarizing plate 131 may transmit only the component of the light EL1, which vibrates in the direction of 90 degrees of the phase axis, among the components of the light ELL Accordingly, light EL2 output from the linear polarizing plate 131 may vibrate in the 90-degree direction.

The phase delay layer 120, that is, the retarder that delays the phase of the light by 45 degrees, may delay the polarization state of the light EL2 having 90 degrees of linearly polarized light by 45 degrees. Accordingly, light EL3 having circularly polarized light of 135 degrees may be output from the phase delay layer 120.

The light EL3 outputted from the phase delay layer 120 may be interfacial reflected according to the abrupt refractive index between a surface 111 of the window glass 110 and the air layer, that is, the refractive index of the interface surface. Interface reflection light RL may have a phase of 135 degrees. The interface reflection light RL may be incident on the phase delay layer 120, and the phase delay layer 120 may delay the phase of the interface reflection light RL by 45 degrees. Accordingly, the light RL1 having the linearly polarized light of 180 degrees may be output from the phase delay layer 120.

The light RL1 output from the phase delay layer 120 may be incident on the linear polarizing plate 131. However, the linear polarizing plate 131 may transmit the incident light, that is, only the component that oscillates in the 90-degree direction of the phase axis of the light RL1. However, since the light RL1 oscillates in the direction of 180 degrees, the light RL1 may not pass through the linear polarizing plate 131. According to this optical mechanism, the interface reflection light RL in the display panel 100 according to an example embodiment of the inventive concepts may be blocked.

Referring to FIG. 3B, the emission light EL emitted from at least some pixels of the plurality of pixels of the pixel layer 140 may pass through the polarizing layer 130 and the phase delay layer 120 as described with reference to FIG. 3A. The light EL3 output from the phase delay layer 120 is transmitted through the surface or interface between the surface 111 of the window glass 110 and the air layer to strike/hit valleys or ridges of the fingerprint FP, and thus the light EL3 may be scattered and reflected by the valleys or ridges thereof. The scattered reflection light SL may vibrate in all directions, not just in a specific direction, such as light EL3 output from the phase delay layer 120.

The scattered reflection light SL may be incident on the window glass 110, and the light SL1 incident on the window glass 110 may be delayed in phase by 45 degrees while passing through the phase delay layer 120.

The light SL2 output from the phase delay layer 120 may be incident on the linear polarizing plate 131. The linear polarizing plate 131 may transmit only the component of the light SL2 that oscillates in the direction of 90 degrees of the phase axis, among components of the light SL2. Accordingly, the light SL3 output from the linear polarizing plate 131 may vibrate in the 90-degree direction.

The light SL3 outputted from the linear polarizing plate 131 may be incident on the retarder 132, and the retarder 132 may delay the polarization state of light SL3 having 90 degrees of linearly polarized light by 45 degrees. Accordingly, light SL4 having circularly polarized light of 135 degrees may be output from the retarder 132.

The light SL4 output from the polarizing layer 130 may be transmitted through the pixel layer 140 through the slit between the pixels PX and then may be transmitted through the substrate 150 in FIG. 1. Light SL5 transmitted through the substrate 150 may be provided to the fingerprint sensor 200. In some embodiments, a light collecting unit for collecting the light may be located on an upper part of the fingerprint sensor 200. The pixel array 210 of the fingerprint sensor 200 may receive the light SL5, that is, sensing light, and may generate an electrical signal corresponding to the sensing light. The read circuit 220 may receive the sensing signals from the pixel array 210 and may generate a fingerprint image based on the sensing signals.

In FIGS. 3A and 3B, the polarizing layer 130 may include a linear polarizing plate 131 and a retarder 132. However, this is only an example, and the polarizing layer 130 may include the linear polarizing plate 131 or may further include a phase shifter other than the linear polarizing plate 131 and the retarder 132.

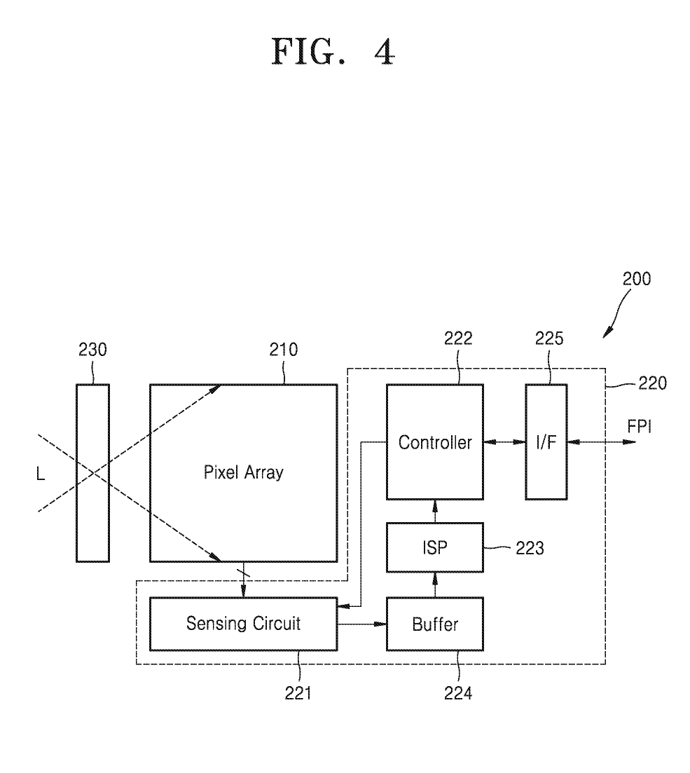

FIG. 4 shows an example of a fingerprint sensor according to an example embodiment of the inventive concepts.

Referring to FIG. 4, a fingerprint sensor 200 may include a pixel array 210, a read circuit 220, and/or a light collecting unit 230.

The light collecting unit 230 may collect or receive the sensing light L incident on the fingerprint sensor 200, for example, the scattered reflection light (SL in FIG. 3B). The sensing light L may be incident on the pixel array 210 through the light collecting unit 230. Without limitation, the light collecting unit 230 may be implemented with a pinhole mask including a plurality of pinholes, an ultra-thin lens, and the like.

The pixel array 210 may include a plurality of sensing pixels (e.g., light-receiving pixels), and each of the plurality of sensing pixels may sense sensing light, that is, the scattered reflection light SL, to generate an electrical signal, that is, a sensing signal.

The read circuit 220 may receive the sensing signals from the plurality of sensing pixels of the pixel array 210 and may generate a fingerprint image FPI through a processing operation on the sensing signals.

The read circuit 220 may include a sensing circuit 221, a controller 222, a signal processor 223, a buffer 224, and/or an interface 225.

The sensing circuit 221 may receive the sensing signals from the pixel array 210 and convert the received sensing signals into digital sensing signals. The sensing circuit 221 may include a signal amplifier, and the signal amplifier may increase the range of sensing signals received from the pixel array 210. In addition, the sensing circuit 221 may include a plurality of analog-to-digital converters, and each of the plurality of analog-to-digital converters may convert a sensing signal provided from a corresponding one of the channels connected to the pixel array 210 into a digital sensing signal. The digital sensing signal may be provided to the signal processor 223 or may be temporarily stored in the buffer 234 and then may be provided to the signal processor 223.

The buffer 224 may temporarily store the digital sensing signal provided from the sensing circuit 221. The buffer 224 may also store various kinds of setting values, algorithms, and the like that are set for the operation of the fingerprint sensor 200. The buffer 224 may be implemented as at least one of a volatile memory or a nonvolatile memory. The non-volatile memory may include read only memory (ROM), programmable ROM (PROM), electrically programmable ROM (EPROM), electrically erasable and erogrammable ROM (EEPROM), a flash memory, phase-change RAM (PRAM), magnetic RAM (MRAM), resistive RAM (RRAM), ferroelectric RAM (FRAM), or the like. The volatile memory may include dynamic random access memory (DRAM), static random access memory (SRAM), synchronous dynamic random access memory (SDRAM), PRAM, MRAM, RRAM, FeRAM, or the like.

The signal processor 223 may generate a fingerprint image FPI based on the digital sensing signals. The signal processor 223 may generate a fingerprint image (FPI) by performing image processing on digital sensing signals based on various image processing techniques.

The controller 222 may control the overall operation of the fingerprint sensor 200. The controller 222 may control the driving timing of the sensing circuit 221. In some embodiments, the fingerprint sensor 200 may operate in synchronization with a display driving circuit that drives the display panel and the controller 222 may receive signals for timing control from a host (e.g., an application processor) or display driving circuit via an interface 225. The controller 222 may transmit the fingerprint image (FPI) to the host through the interface 225.

The interface 225 may include one of an red, green and blue (RGB) interface, a central processing unit (CPU) interface, a serial interface, a mobile display digital interface (MDDI), an inter integrated circuit (I2C) interface, a serial peripheral interface (SPI), a micro controller unit (MCU), a mobile industry processor interface (MIPI), an embedded display port (eDP) interface, a D-subminiature (D-sub) interface, an optical interface, or a high definition multimedia interface (HDMI). Additionally or alternatively, the interface 225 may include, for example, a mobile high-definition link (MHL) interface, a secure digital (SD) card, a multi-media card (MMC) interface or an infrared data association (IrDA) standard interface. In addition, the interface 225 may include various serial or parallel interfaces.

The components of the read circuit 220 may be implemented using processing circuitry. The term “processing circuitry,” as used in the present disclosure, may refer to hardware and/or a combination of hardware and software. For example, the processing circuitry may include a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions (e.g., computer-readable instructions) in a defined manner.

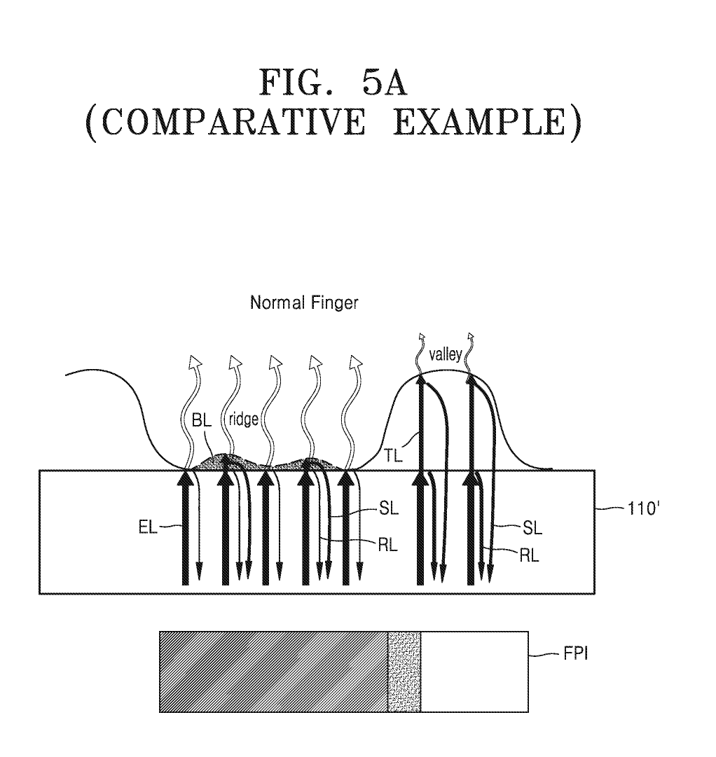

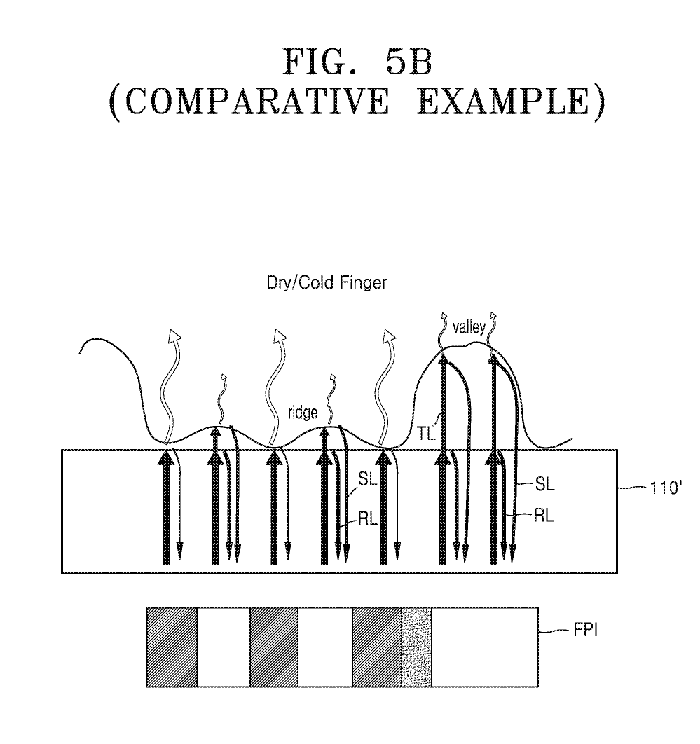

FIGS. 5A and 5B are views explaining a change of an optical fingerprint image based on a state of a finger in a fingerprint sensing system using a display panel according to a comparative example of a display panel, according to some embodiments of the inventive concepts.

As described above with reference to FIGS. 1 to 3B, since the display panel 100 or 100a according to some embodiments of the inventive concepts may include a phase delay layer 120 between the window glass 110 and the polarizing layer 130, due to such an optical structure, the interface reflection light generated by reflecting the light emitted from the pixels on the interface surface between the window glass 110 and the air layer may be reduced or prevented from being incident on the fingerprint sensor. However, the display panel according to the comparative example may not include the phase delay layer 120, and thus the fingerprint sensor may receive the interface reflection light to generate the fingerprint image based on the interface reflection light.

Referring to FIG. 5A, the light EL emitted from a pixel layer may be interfacially reflected by an abrupt refractive index change at an interface surface between a window glass 110′ and the air layer, and thus the interface reflection light RL may be incident into the window glass 110′. When a finger in the normal state is in contact with the window glass 110′, a buffer layer BL for reinforcing a contact surface of a ridge due to sweat secreted through a ridge pore may be formed. Accordingly, in the ridge portion, the amount of the interface reflection light RL is very small, and a considerable amount of the light TL transmitted through the window glass 110′ may be also absorbed into a skin layer. On the other hand, the amount of interface reflection light RL may be relatively large in the valley portion. Thus, a fingerprint image FPI in which a portion corresponding to the ridge portion is dark and other portion corresponding to the valley portion is bright may be generated.

Referring to FIG. 5B, since the secretion of sweat through the pores is small when a dry finger touches the window glass 110′, a buffer layer may not be formed in a ridge portion, and a large amount of interface reflection light RL may be incident on the fingerprint sensor. Thus, some portions corresponding to the ridge portion appear bright, and thus a phenomenon in which a ridge appears to be broken in a fingerprint image FPI may occur. As described above, in the fingerprint sensing system to which the display panel according to the comparative example is applied, the fingerprint image FPI may be changed depending on the state of the finger such as the degree of moisture and the degree of oil, and thus the fingerprint image FPI may be distorted or damaged.

However, as described above, the fingerprint sensing system 10 in FIG. 1 according to some embodiments of the inventive concepts may be configured such that the display panel 100 blocks the interface reflection light RL and transmits the scattered reflection light SL, and thus the fingerprint sensor 200 may generate an image based on the scattered reflection light SL. As illustrated in FIGS. 5A and 5B, some of the light transmitted through the window glass 110′ may be scattered by rubbing against the ridges and the valleys, and thus the scattered reflection light SL may be incident on the window glass 110′. The amount of scattered reflection light SL may be determined by a distance from the window glass 110 to the scattered point, for example, the epidermis of a ridge and a valley. Since the amount of scattered reflection light SL has little influence depending on the state of the finger, the fingerprint sensor 200 may generate a fingerprint image at a certain level of fingerprint image regardless of the state of the finger.

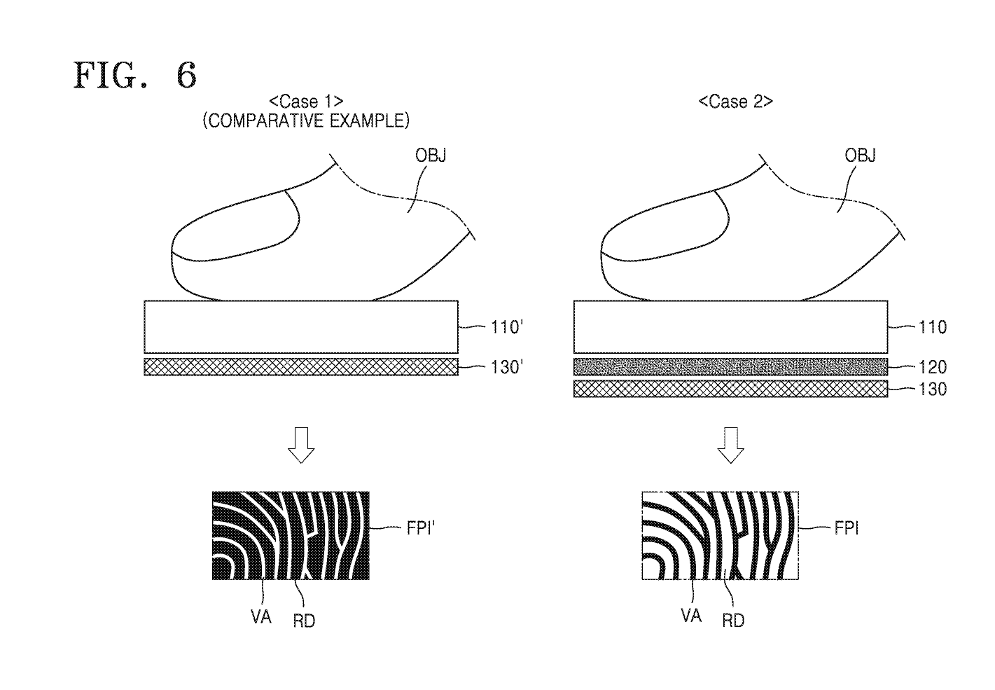

FIG. 6 is a view for explaining a comparison of fingerprint images generated in a fingerprint sensing system to which a display panel according to an example embodiment of the inventive concepts is applied and fingerprint images generated in the fingerprint sensing system to which a display panel according to the comparative example is applied.

Case 1 shows a fingerprint image FPI′ generated in a fingerprint sensing system to which a display panel according to a comparative example is applied, and Case 2 shows a fingerprint image FPI generated in a fingerprint sensing system 10 in FIG. 1 to which a display panel 100 in FIG. 1 according to an example embodiment of the inventive concepts is applied.

As shown in Case 1, the display panel according to the comparative example may not include a phase delay layer between A polarizing layer 130′ and the window glass 110′. Therefore, when an object OBJ, that is, a fingerprint of a finger, is sensed, the interface reflection light may be not blocked, and a fingerprint image FPI′ may be generated based on the interface reflection light. Therefore, a fingerprint image FPI′ in which the valleys VA are bright and the ridge RD is dark may be generated.

As shown in Case 2, a display panel according to an example embodiment of the inventive concepts may include a phase delay layer 120 between the polarizing layer 130 and the window glass 110. Accordingly, the interface reflection light may be blocked and the fingerprint image FPI may be generated based on the scattered reflection light which is generated by scattering and reflecting the light that hits/collides valleys the epidermis of VA and ridges RD of fingerprints. The amount of scattered reflection light may be determined by a distance from the window glass 110 to the scattered point, for example, the epidermis of a ridge and a valley. Since the ridge RD is located closer to the window glass 110 than the valley VA, the amount of the scattered reflection light of the ridge RD may be greater than the amount of the scattered reflection light of the valley VA. Therefore, a fingerprint image FPI in which the ridge RD is bright and the valley VA is dark may be generated.

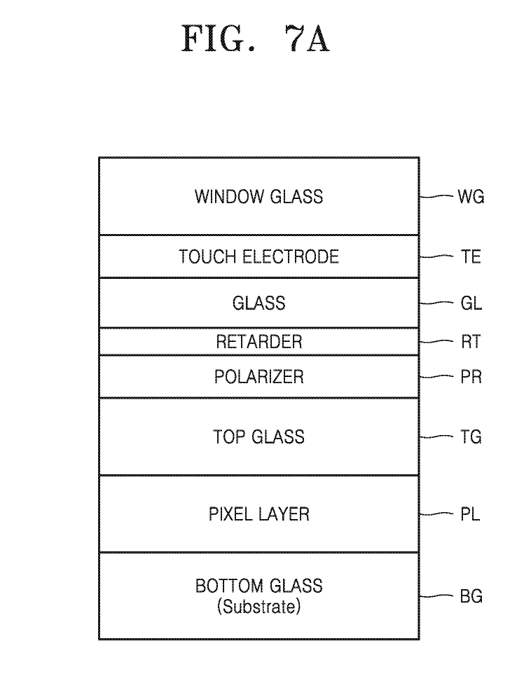

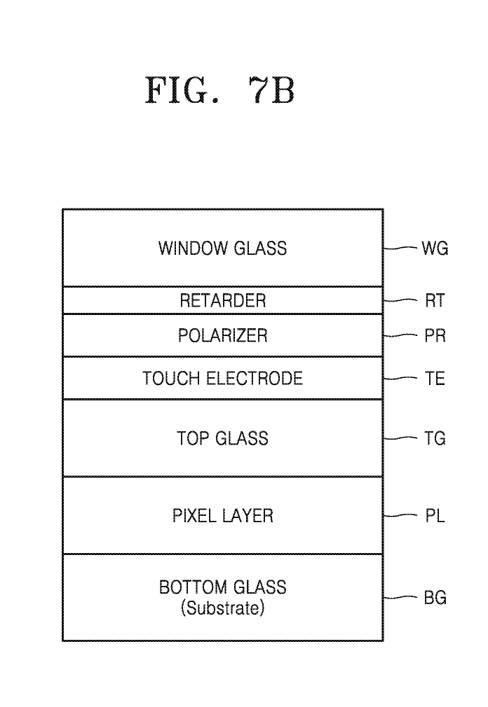

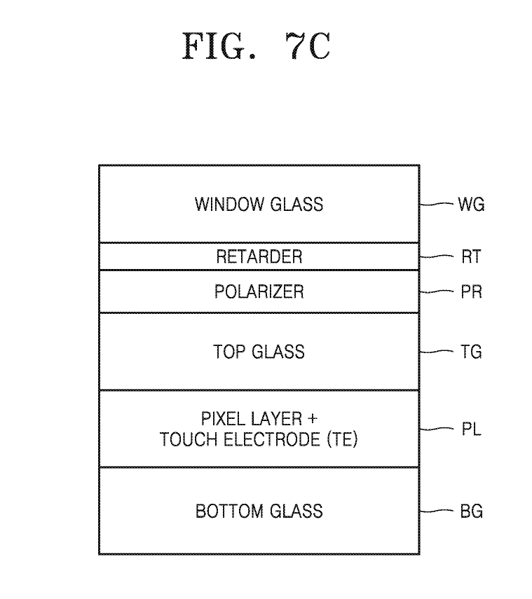

FIGS. 7A to 7C are example vertical cross-sectional views illustrating a structure of a display panel according to an example embodiment of the inventive concepts. FIGS. 7A to 7C show a structure of a display panel (or a touch screen panel) including a touch electrode.

Referring to FIG. 7A, a touch electrode TE, a glass GL, a retarder RT, a polarizing plate PR, a top glass TG, a pixel layer PL, and/or a bottom glass BG may be sequentially stacked below a window glass WG. The retarder RT, the polarizing plate PR, and the bottom glass BG may correspond to the phase delay layer 120, the polarizing layer 130, and the substrate 150 of FIG. 1, respectively. According to some embodiments, a touch panel may be formed separately from the display panel, and the touch electrode TE may be patterned on the glass GL, that is, a dedicated substrate of the touch panel.

Referring to FIG. 7B, a retarder RT, a polarizing plate PR, a touch electrode TE, a top glass TG, a pixel layer PL, and/or a bottom glass BG may be sequentially stacked below a window glass WG. According to some embodiments, the display panel may be formed in an on-cell type in which the touch electrode TE is patterned on the top glass TG of the display panel.

Referring to FIG. 7C, a retarder RT, a polarizing plate PR, a top glass TG, a pixel layer PL, and/or a bottom glass BG may be sequentially stacked below a window glass WG. According to some embodiments, the display panel may be formed as an in-cell type in which the touch electrode TE is formed integrally with a pixel. In some embodiments, one of the electrodes constituting the pixel may be used as the touch electrode TE. For example, a common electrode of the pixel may be used as the touch electrode TE.

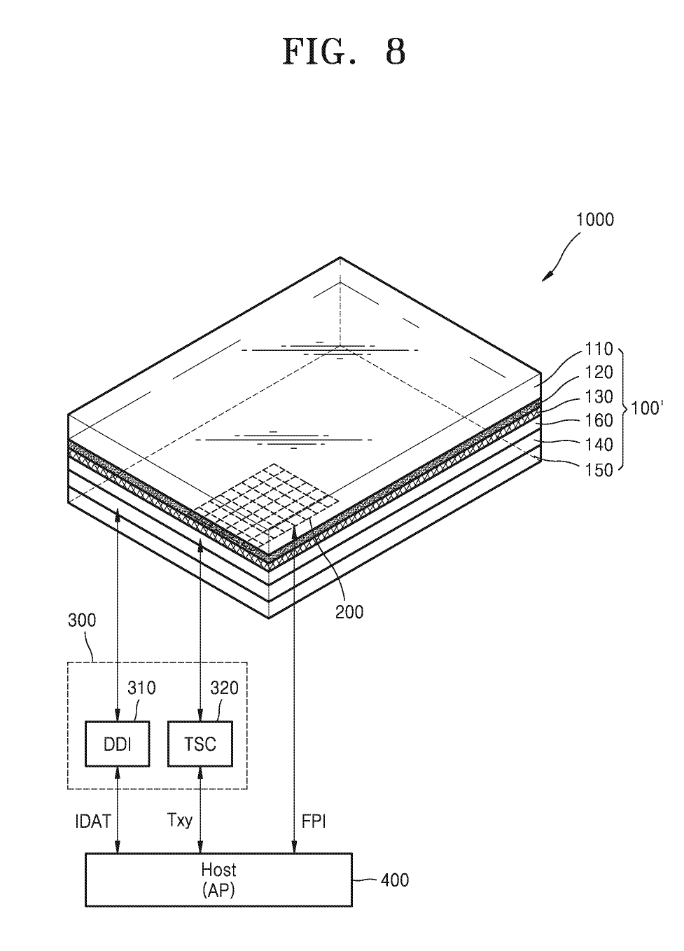

FIG. 8 is a view showing an electronic device including a display panel according to an example embodiment of the inventive concepts.

Referring to FIG. 8, an electronic device 1000 may include a fingerprint sensing system including a display panel 100′ and a fingerprint sensor 200, a driving circuit 300 for driving the display panel 100′, and a host 400. For example, the host 400 may be an application processor (AP).

The display panel 100′ may include a window glass 110, a phase delay layer 120, a polarizing layer 130, a touch sensing layer 160 (or a touch panel), a pixel layer 140, and/or a substrate 150. The descriptions already given above of the window glass 110, the phase delay layer 120, the polarizing layer 130, the pixel layer 140, and the substrate 150 with reference to FIG. 1 are omitted. The display panel 100′ of FIG. 8 may include a touch sensing layer 160 in which a plurality of touch electrodes are formed. In FIG. 8, the touch sensing layer 160 may be formed below the polarizing layer 130, but is not limited thereto. As described with reference to FIGS. 7A to 7C, the touch sensing layer 160 may be formed on the phase delay layer 120 or may be integrally formed with the pixel layer 140. The touch sensing layer 160 may sense a user's touch operation. For example, the touch sensing layer 160 in the capacitive type may include sensing units whose capacitance values vary based on the user's touch.

The fingerprint sensor 200 may be positioned below the display panel 100′. As described above, a fingerprint image FPI may be generated base on the scattered reflection light generated when the light output from the pixel layer 140 hits the fingerprint and may provide the generated fingerprint image FPI to the host 400. The host 400 may perform functions such as user authentication and security authentication of the electronic device 1000 based on the fingerprint authentication based on the fingerprint image FPI.

The driving circuit 300 may include a display driving circuit (or display driver circuit) 310, and a touch controller 320. The display driving circuit 310 may convert video data IDAT provided from the host 400 into a video signal and may provide the video signal to the display panel 100′ to display the video on the display panel 100′. The touch controller 320 may sense the capacitance change of the sensing units of the touch sensing layer 160 to generate a touch sensing result. As an example, the touch controller 320 may provide a driving signal for driving the touch sensing layer 160 and may receive and process an electrical signal according to the capacitance variation of the sensing units in the touch sensing layer 160. The touch controller 320 may calculate touch coordinates Txy to provide the calculated touch coordinates Txy to the host 400.

The host 400 may control the driving circuit 300 and the fingerprint sensor 200 and may perform functions of the electronic device 1000 based on the data provided from the driving circuit 300 and the fingerprint sensor 200, for example, the touch coordinates Txy and the fingerprint image FPI. According to some example embodiments, the driving circuit 300 and/or the host 400 may be implemented using processing circuitry.

In some embodiments, the display driving circuit 310, the touch controller 320, and/or the fingerprint sensor 200 may communicate with each other or may communicate via the host 400. For example, the display driving circuit 310 may provide a timing signal indicating a display driving time point to the touch controller 320, and the touch controller 320 may perform touch sensing on a non-display time period based on the timing signal. The touch controller 320 may sense a touch input generated by the display panel 100′ to provide the sensed touch input to the host 400. The host 400 may control the fingerprint sensor 200 to perform fingerprint sensing based on the touch input and may control the display driving circuit 310 to drive the display panel 100′. In such a manner, the display driving circuit 310, the touch controller 320, and the fingerprint sensor 200 may communicate with each other to perform a display driving operation, a touch sensing operation, and a fingerprint sensing operation.

In some embodiments, the driving circuit 300 may be implemented as one semiconductor chip. The display driving circuit 310 and the touch controller 320 may be integrated on one semiconductor substrate. In some embodiments, at least a part of the read circuit 220 of the fingerprint sensor 200 in FIG. 4 may be integrated with the display driving circuit 310 or the touch controller 320 on one semiconductor substrate.

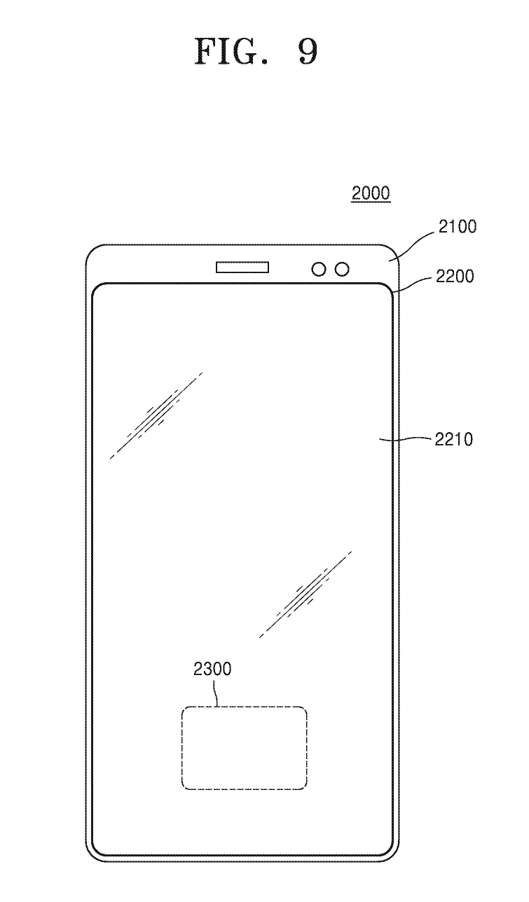

FIG. 9 is a diagram illustrating a smartphone according to some embodiments of the inventive concepts.

Referring to FIG. 9, a smartphone 2000 may include a display panel 2200, a housing 2100, and/or a fingerprint sensor 2300. The fingerprint sensor 2300 may be in the housing 2100 and the lower portion of the display panel 2200. The smartphone 2000 may also include an application processor (AP) for controlling the overall operation of the smartphone 2000 and a driver circuit for driving the display panel 2200, such as a display driving circuit and a touch controller.

The housing 2100 may form an appearance of the smartphone 2000 and may protect components such as integrated circuits, batteries, and antennas within the smartphone from external shocks or scratches.

The display panel 2200 may operate as an input/output device of the smartphone 2000 by performing display, touch sensing, and fingerprint sensing operations. The display panel described with reference to FIGS. 1 to 8 may be applied as the display panel 2200 of some embodiments of the inventive concepts. As described above, a phase delay layer and a polarizing layer may be stacked below a window glass 2210 of the display panel 2200.

The fingerprint sensor 2300 may be an optical fingerprint sensor which is under the display panel 2200. The light emitted from the pixel layer of the display panel 2200 may hit the ridges and the valleys of the fingerprint to generate the fingerprint image based on the scattered reflection light. Since the area for fingerprint sensing overlaps with the display area, a separate space for the fingerprint sensor is not required in front of the smartphone 2000. Accordingly, the display panel 2200 may have a wide area as possible in a front portion of the smartphone 2000.

In addition, as described above, the fingerprint sensor 2300 generates a fingerprint image on the basis of scattered reflection light rather than interface reflection light, and thus a fingerprint image free from distortion or damage may be generated regardless of the environment in which the smartphone 2000 is used, the state of the user's finger, and the like. Therefore, the fingerprint authentication function of the smartphone 2000 may be improved.

As described above, example embodiments of the inventive concepts have been disclosed. Although the inventive concepts have been described with reference to the embodiments illustrated in the drawings, it is only an example, and it is to be understood that various modifications and equivalent embodiments may be made by those skilled in the art without departing from the scope of the inventive concepts.

According to the display panel according to some embodiments of the inventive concepts, interface reflection light whose amount of light changes according to a state of the finger may be substantially or fully blocked from entering an optical fingerprint sensor provided below the display panel, and the scattered reflection light scattered on the ridge or ridge of the fingerprint may be incident on the fingerprint sensor. Accordingly, the fingerprint sensing system including the display panel according to the inventive concepts may generate the fingerprint image without distortion, regardless of the state of the finger touching the display panel, by generating the fingerprint image based on the scattered reflection light.

While the inventive concepts have been particularly shown and described with reference to embodiments thereof, it will be understood that various changes in form and details may be made therein without departing from the spirit and scope of the following claims.

What is claimed is:

1. A display panel for providing sensing light to an optical fingerprint sensor, the display panel comprising:
a window glass;
a phase change layer under the window glass and configured to delay a phase of light;
a polarizing plate under the phase change layer;
a pixel layer under the polarizing plate and having a plurality of pixels each emitting light; and
a substrate under the pixel layer and configured to transmit the sensing light generated by scattering light emitted from at least a part of the plurality of pixels by a fingerprint on the window glass.

2. The display panel of claim 1, wherein the phase change layer delays the phase of the light by 45 degrees.

3. The display panel of claim 2, wherein the phase change layer blocks interface reflection light generated by reflecting light output from at least some of the plurality of pixels by an interface between the window glass and an air layer.

4. The display panel of claim 1, wherein the polarizing plate comprises:
a retarder configured to delay a phase of the light; and
a linear polarizing plate that transmits components of the light that oscillate along a designated phase axis.

5. The display panel of claim 1, wherein an amount of light corresponding to a ridge of the fingerprint in the sensing light is greater than the amount of light corresponding to a valley of the fingerprint.

6. The display panel of claim 1, wherein the optical fingerprint sensor is below the substrate.

7. The display panel of claim 1, wherein each of the plurality of pixels comprises an organic light emitting diode.

8. The display panel of claim 1, further comprising a touch sensing layer on which touch electrodes are located.

9. A display panel comprising:
a pixel layer on a substrate and comprising a plurality of pixels;
a polarizing layer on the pixel layer;
a window glass on the polarizing layer; and
a filter between the polarizing layer and the window glass and configured to block interface reflection light that is emitted from at least a part of the plurality of pixels and reflected from one surface of the window glass.

10. The display panel of claim 9, wherein the filter comprises a retarder configured to delay a phase of light that is incident by λ*(N/4) (where λ is wavelength and N is one of 1, 3, 5, or 7).

11. The display panel of claim 9, wherein the light emitted from the at least a part of the plurality of pixels is scattered and reflected by a fingerprint on the window glass and is provided to an optical fingerprint sensor below the substrate.

12. The display panel of claim 9, wherein the polarizing layer comprises a circular polarizing plate.

13. The display panel of claim 12, wherein the circular polarizing plate comprises a retarder and a linear polarizing plate, wherein the linear polarizing plate is closer to the filter than the retarder.

14. A fingerprint sensing system comprising:
a display panel; and
a fingerprint sensor configured to generate a fingerprint image based on sensing light generated by scattering and reflecting light emitted from the display panel on a fingerprint,
wherein the display panel comprises:
a pixel layer comprising a plurality of pixels emitting light;
a polarizing plate on the pixel layer;
a retarder on the polarizing plate and configured to retard a phase of light by 45 degrees; and
a window glass on the retarder.

15. The fingerprint sensing system of claim 14, wherein the retarder reduces interface reflection light, which is generated by reflection of an interface surface between the window glass and an air layer, from being incident on the fingerprint sensor.

16. The fingerprint sensing system of claim 14, wherein a light amount corresponding to ridges of the fingerprint in the sensing light is greater than a light amount corresponding to valleys of the fingerprint in the sensing light.

17. The fingerprint sensing system of claim 14, wherein the fingerprint sensor generates a fingerprint image in which a portion corresponding to a ridge of the fingerprint is brighter and other portion corresponding to a valley of the fingerprint is darker.

18. The fingerprint sensing system of claim 14, wherein the fingerprint sensor is below the display panel.

19. The display panel of claim 14, wherein each of the plurality of pixels comprises an organic light emitting diode.

20. The display panel of claim 14, wherein the display panel further comprises a touch sensing layer in which touch electrodes are formed.
